(19) United States
(12) Patent Application Publication
(10) Pub. No.: US 2009/0261708 A1
(43) Pub. Date: Oct. 22, 2009

(54) GLASS-PHOSPHOR CAPPING STRUCTURE FOR LEDS

(75) Inventors: Yaakov Moseri, Shoham (IL); Eyal Brami, Matan (IL); Nissim Cohen-Matzliah, Tel Aviv-Yaffo (IL); Shlomo Kazma, Petah Tikva (IL); Eli Margalit, Ra'Anana (IL); Yitzhak Meyuchas, Ganei Tikva (IL); Yossef Schneider, Patach Tikva (IL)

Correspondence Address: MOTOROLA, INC., 1303 EAST ALGONQUIN ROAD, IL01/3RD, SCHAUMBURG, IL, 60196, US

(73) Assignee: MOTOROLA, INC., SCHAUMBURG, IL (US)

(21) Appl. No.: 12/106,559

(22) Filed: Apr. 21, 2008

(51) Int. Cl. H01L 33/00

(52) U.S. Cl. 313/501; 438/27; 257/E33.061

(57) ABSTRACT

An LED and method for increasing the reliability of LEDs are provided. The LED contains a semiconductor die, a reflector, and a glass capping structure. The glass structure may be solid or formed from multiple layers of uniform or varying dimensions. The glass structure is coated with a phosphor that emits light of a different wavelength than the die. The phosphor is disposed between adjacent layers if the glass structure has multiple layers. The die is disposed in a cavity of the reflector. The cavity may be evacuated or filled with a transparent material.

### TECHNICAL FIELD

The present application relates to LEDs. In particular, the application relates to a glass capping structure for an LED.

### BACKGROUND

A light-emitting diode (LED) contains a semiconductor die that emits light when a current is applied thereto. The semiconductor die is encapsulated in material that is transparent (i.e., transparent to the wavelengths emitted by the semiconductor die) such as epoxy or silicone to protect the semiconductor. Light from the LED thus impinges on the encapsulation material before propagating out of the package. It is desirable for the encapsulation material to remain transparent for an extended period of time. In time, however, the encapsulation material degenerates, eventually becoming hazy or colored. This causes a reduction in the transparency of the encapsulation material. As a result, the light output from the LED decreases over time. The speed of degeneration is especially sensitive to the device temperature. The temperature of the device increases due to, for example, the ambient environment and heat radiated by the semiconductor die during operation for extended periods of time.

It is desirable to provide an LED in which the encapsulation material is able to better withstand such degeneration.

### BRIEF DESCRIPTION OF THE DRAWINGS

Embodiments will now be described by way of example with reference to the accompanying drawings, in which:

FIG. 1 is a cross-sectional view of a first embodiment of an LED.

FIG. 2 is a cross-sectional view of a second embodiment of an LED.

FIG. 3 is a cross-sectional view of a third embodiment of an LED.

FIG. 4 is a cross-sectional view of a fourth embodiment of an LED.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments. Also, common but well-understood elements that are useful or necessary in a commercially feasible embodiment are often not depicted to facilitate viewing clarity. It will further be appreciated that certain actions and/or steps may be described or depicted in a particular order of occurrence while those skilled in the art will understand that such specificity with respect to sequence is not actually required.

### DETAILED DESCRIPTION

An LED and method for increasing the reliability of LEDs are provided by decreasing the degradation of light intensity caused by exposure of the LED to elevated temperatures. The LED contains a semiconductor die, a conductor, a reflector, and a glass capping structure. The glass capping structure is coated with a phosphor and may have multiple layers of varying dimensions. The glass capping structure may have a variety of shapes, such as a frustro-pyramidal shape.

The degradation of the light output of an LED is primarily determined by the degradation of the semiconductor die, the encapsulating material, and the phosphor, if present. Of these components, the phosphor used is generally stable over time at the temperatures in the LED package. The light output of the semiconductor initially increases slightly (known as burn-in) and then decreases slowly as the number of defects in the semiconductor crystal increases. Epoxy or silicone such as that used in conventional encapsulating material degrades considerably faster over both temperature and time than phosphor or the die. Despite this problem, these encapsulating materials are used as they are cheap and relatively easy to prepare, as well as the LED being relatively easy to fabricate.

As indicated previously, the light output degradation is especially problematic for LEDs and displays in which the temperature of the encapsulating material is elevated. This includes environments in which the ambient temperature is elevated or high brightness and white LEDs, in which the LEDs are driven harder (i.e., use a larger operating current), leading to a higher temperature.

Environments in which the temperature is elevated include closed vehicles, areas in which the LED is exposed to strong direct sunlight, and other high-heat climates. Temperatures in these environments can reach 70-80° C. or higher. The encapsulation material is initially relatively transparent (i.e., transparent to the wavelengths emitted by the semiconductor and phosphor if present), transmitting about 70-80% of the LED light. However, as noted above, the transparency quickly degenerates under these harsh conditions. LED ratings by manufacturers correspond to the average time to reach 50% of their initial brightness. However, although LEDs are rated to last for a large number (usually tens of thousands) of hours, such ratings are for much lower ambient temperatures. In one example, tests of LED brightness degradation after 1000 hours of operating in an ambient testing environment (oven) of 100° C. show a much faster degradation, degrading to about 64% to about 47% of the initial light output.

The LED embodiments described herein employ glass as the encapsulating material. The transmissibility of the glass is higher than that of silicone or epoxy and is relatively unaffected by the elevated temperatures encountered by the LED. Thus, the LED can be exposed to these elevated temperatures for extended periods of time without substantially degrading the optical output.

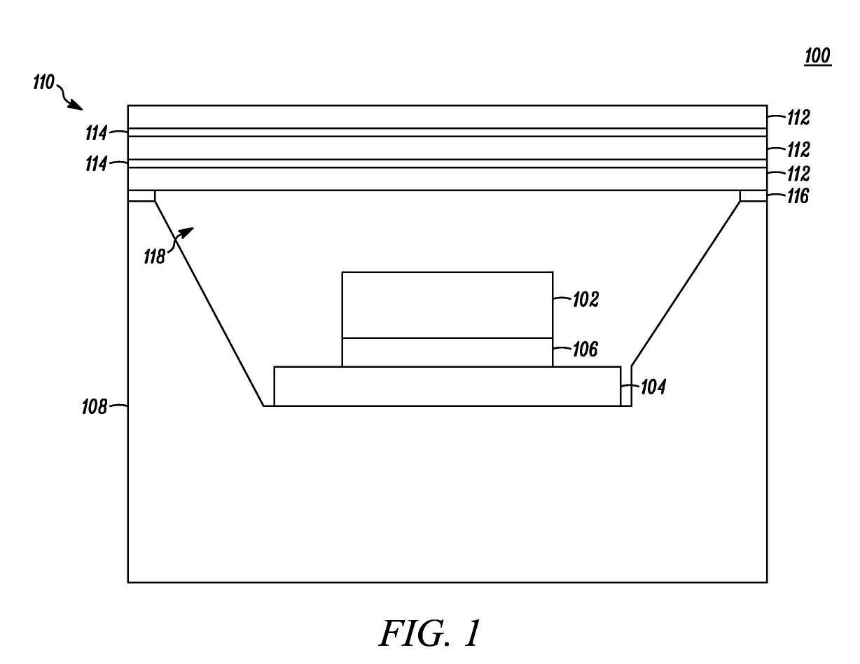

One embodiment of an LED is shown in FIG. 1. As shown, LED 100 contains a semiconductor die 102, a conductive flange 104, an adhesive 106, a reflector 108, and a capping structure 1 10. The die 102 contains one or more individual light emitters formed from, for example, a III-V or II-VI compound. These compounds can be binary, ternary, quaternary, or other compounds that emit light in a desired wavelength region (generally visible or near UV) such as InGaAsP, AlInGaP, AlInGaAsP, GaN, or InGaN.

The die 102 is attached to the conductive flange 104 through adhesive 106. The flange 104 is formed from a metal, such as Al or Cu. The flange 104 extends from the die 102 to outside the LED 100 such that the flange 104 can transmit current to the die 102. Thin gold wires (not shown) are disposed between the flange 104 and the die 102 to supply the operating current to the die 102. The adhesive 106 is thermally conductive and may be transparent. This permits the flange 104 to supply power to the die 102 and, to some extent, act as a heat sink for the die 102. Another flange (not shown) is connected to the die 102 such that a circuit can be completed and current can be passed through the die 102, thereby permitting the die 102 to emit light.

The reflector 108 is formed from white resin such as PolyPhthalAmide (PPA) and reflects light that was emitted by the die 102 away from the front of the LED 100 back towards the front of the LED 100. The reflector 108 may alternately be formed from any material that reflects a substantial amount of the light impinging on it, such as a metal. As shown in FIG. 1, the die 102, flange 104, and adhesive 106 are retained within a cavity 118 formed in the reflector 108.

The capping structure 110 is a laminate that contains layers 112 of glass that are attached to each other using a transparent adhesive layer 114. A phosphor may be mixed in the adhesive layer 114, which is then applied to the glass layer 112. Alternatively, the glass layer 112 may first be coated with the phosphor and the adhesive layer 114 then disposed on the combined glass/phosphor layer. The phosphor may be coated on the glass layer 112 by spattering or some other similar technique that allows precision control of the amount of phosphor deposited. The amount of the phosphor provided in the capping structure 110 depends on the phosphor spattering thickness and by number of glass layers on which the phosphor is deposited. Although only three glass and adhesive layers are shown, a fewer or greater number may be present.

The glass may be formed from any number of known materials, such as pure silica, silica containing components such as Na₂CO₃, CaO, and MgO, or glasses that do not include silica as a major constituent, e.g., fluorozirconate, fluoroaluminate, aluminosilicate, phosphate, and chalcogenide glasses in a known manner.

The capping structure 110 can be of any desired shape, e.g., rectangular, square, or circular when viewed in a direction perpendicular to the top of the LED 100, e.g., looking through the capping structure 100 to the die 102. The capping structure 110 can be formed as a lens such that the light from the LED 100 is focused or scattered, dependent on the shape of the lens.

Different types of LEDs, such as white LEDs, may contain a phosphor. The phosphor absorbs light of one wavelength range, which is emitted by the die 102, and re-emits the light at a different wavelength. This permits a wide variety of colors to be emitted by the LED 100, dependent on the choice of phosphor and particular semiconductor used in the die 102. For example, for LEDs that emit white light, the die 102 emits light in the blue portion of the visible spectrum or near UV portion of the spectrum. This blue or UV light is absorbed by the phosphor and re-emitted as white light. In one example, the phosphor is silicate. Phosphors that emit other color light may also be used. Standard phosphors that provide white and other color light under such conditions are known and will not be further described.

The amount of phosphor in the capping structure 110 is one factor in determining the intensity of the light emitted from the LED 100. Phosphor may be present between some or all of the glass layers 112, dependent on the desired characteristics of the LED 100.

In addition, in some embodiments, to altering the wavelength of the light from the LED 100, the capping structure 110 also protects the die 102 from damage. The adhesive layer 114 is transparent in the wavelength ranges of the die 102 and the phosphor. One example of such an adhesive is “NORLAND 68.” Such an adhesive has good light transmission, optical clarity, low out-gassing and a good thermal expansion coefficient. Similarly, the glass layers 112 are about 95% transparent, experience less aging over time, are more resistant to thermal cycling (which occurs when the LED 100 alternates between a normal operating environment of, say, 20° C., and an extreme environment), and are able to operate over a wider temperature range of, e.g., −30° C. to 70° C. than an encapsulating material such as silicone or epoxy.

The capping structure 110 is attached to the reflector 108 using an adhesive 116. The adhesive 116 may be formed from the same material as the adhesive layer 114. Alternately, the adhesive 116 may be formed from material other than that forming the adhesive layer 114. The adhesive 116 need not be transparent as it is disposed only at the corners between the capping structure 110 and the reflector 108, and thus minimal light is transmitted through it.

As shown in the embodiment of FIG. 1, the glass layers 112 are each of substantially uniform thickness and extend to cover substantially the entirety of the front surface of the LED 100. Similarly, each of the adhesive layers 114 is of substantially uniform thickness and extends to cover substantially the entirety of the glass layers 112 between which it is disposed. Although not shown, the lowermost glass layer 112 closest to the die 102 may also be coated with phosphor.

The LED 100 may be assembled in a low pressure chamber. This permits the cavity 108 of reflector 108 (in which the die 102 is disposed) to be evacuated (i.e., not filled with material). Such an arrangement reduces the degradation of the die 102 caused, e.g., by exposure of the die 102 to oxygen. The cavity 108 could alternately be filled with a transparent material such silicone or epoxy. This latter arrangement may be easier to manufacture, but suffers from some of the degradation problems above. However, the problems are less severe as, in the latter arrangement a large proportion of the light emitted by the die 102 is transmitted directly toward the capping structure 110 rather than being reflected by the reflector 108. This direct light passes through only a relatively thin layer of the transparent material and thus suffers a minimal amount of degradation.

Alternately, the cavity 118 can be filled with an inert gas, such as nitrogen. It is desirable that the inert gas is dry and may be at least about 99.9% percent pure. This can help to prevent oxygen from entering the cavity 118 as well as helping to maintain good transparency in the light path between the die 102 and the glass layers 112.

To fabricate the LED 100, the die 102 is attached to the flange 104 via the adhesive 106. The die 102 and attached flange 104 may be attached to the reflector 108 via an adhesive (not shown) to form a reflector structure. Turning to the capping structure 110, the glass layers 112 are coated with the adhesive layer 114 containing the phosphor and attached together. Alternately, the glass layers 112 are coated with the phosphor, the adhesive layer 114 (that may or may not contain phosphor) applied to the coated glass layers 112, and the glass layers 112 attached together. The capping structure 110 may be assembled before or after the reflector structure is assembled. Once the capping structure 110 has been assembled, the capping structure 110 is attached to the reflector structure using adhesive 116. The capping structure 110 can be attached to the reflector structure in a low pressure chamber such that the cavity 118 of the reflector 108 is evacuated. Alternately, the cavity 118 may be filled with a transparent material and the capping structure 110 then attached to the reflector structure.

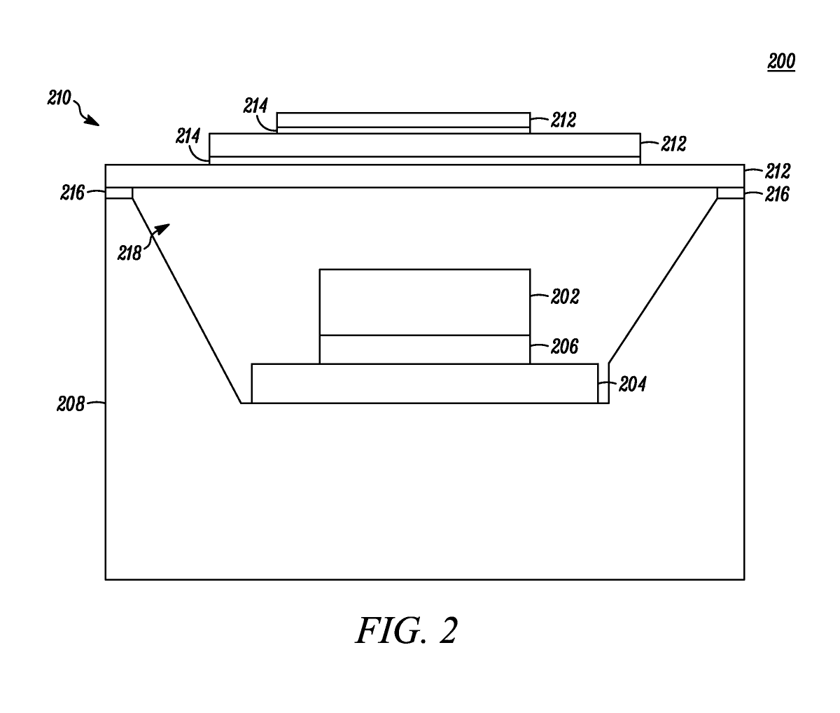

The embodiment of FIG. 1 illustrates a capping structure 110 in which the individual glass layers 112 are of uniform dimensions and the individual adhesive layers 114 are of uniform dimensions (which may or may not be different from that of the glass layers 112). However, the various dimensions may be different for different layers. Such an embodiment is shown in FIG. 2.

The LED 200 of FIG. 2 is similar to the LED 100 of FIG. 1, and contains the semiconductor die 202, the conductive flange 204, and the adhesive 206 disposed in the cavity 218 of the reflector 208. A capping structure 210 is attached to the reflector 208 using an adhesive 216.

The capping structure 210 contains glass layers 212 attached to each other using adhesive layer 214. The adhesive layer 214 contains the phosphor, or the glass layer 212 is coated with the phosphor and the adhesive layer 214 then disposed on the combined glass/phosphor layer in a manner similar to that above. In the embodiment of FIG. 2, unlike that of FIG. 1, the glass layers 212 have different dimensions. Similarly, the adhesive layers 214 may have different dimensions. Specifically, as shown in the cross-sectional view of FIG. 2, the thickness and lateral dimension of the glass layers 212 decrease with increasing distance from the die 102, with the thickness and length of a particular glass layer 212 being uniform. The lateral dimension is in the right-left direction in FIG. 2. Similarly, the lateral dimension of the adhesive layers 214 decreases with increasing distance from the die 102, with the lateral dimension of a particular adhesive layer 214 being uniform. The thickness of the adhesive layers 214 may be the same or different. The lateral dimension of the glass layer 212 and underlying adhesive layer 214 is the same in the embodiment of FIG. 2. Although not shown due to the cross-sectional view, the lateral dimension of the glass layers 212 and/or adhesive layers 214 that is perpendicular to that illustrated in FIG. 2 can also vary in a similar or different manner as the lateral dimension shown. Alternately, one of the lateral dimensions may remain uniform while the other changes. The capping structure 210 has a frusto-pyramidal or frusto-conical shape that appears as a trapezoid in the cross-sectional view of FIG. 2. As above, the number of layers may be adjusted as desired and phosphor may be disposed on the lowest glass layer 212. The cavity 218 can be evacuated or filled with encapsulating material, as above.

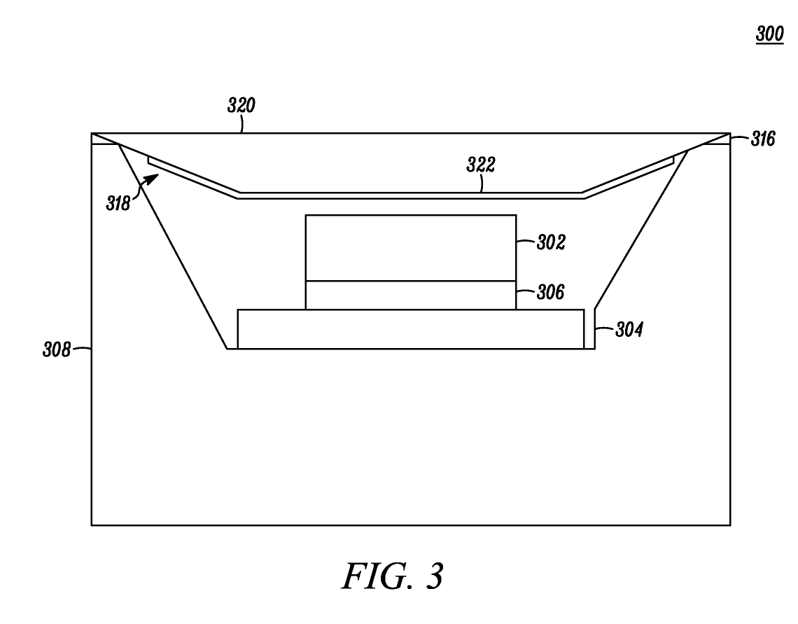

Rather than being a laminated structure, as shown in FIGS. 1 and 2, the capping structure can be a single glass layer as shown in the embodiment of FIG. 3. The LED 300 of FIG. 3 is similar to the LEDs 100, 200 of FIGS. 1 and 2. The LED 300 contains the semiconductor die 302, the conductive flange 304, and the adhesive 306 disposed in the cavity 318 of the reflector 308. Instead of a laminated capping structure, however, the LED 300 contains a capping structure that is a glass “hat” 320. The hat 320 is attached to the reflector 308 using the adhesive 316. The hat 320 has an inverted frusto-pyramidal or frusto-conical shape that appears as a trapezoid in the cross-sectional view of FIG. 3. As shown, the hat 320 decreases in lateral dimension with decreasing distance from the die 302 (and thus is inverted). A layer of phosphor 322 covers substantially the entirety of the lower surface of the hat 320. Similar to the capping structure 210 of FIG. 2, the hat 320 may lens the light to concentrate or spread the light from the LED 300.

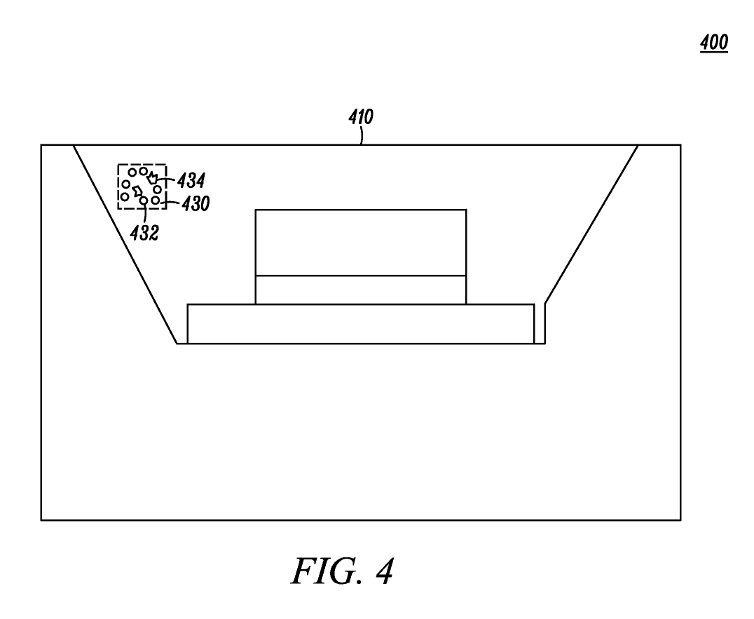

Rather than using a solid glass encapsulation, it may be desirable from a cost and/or production standpoint to use an encapsulation material in which a substantial amount of glass is deployed. Such an embodiment is illustrated in FIG. 4. As shown, the LED 400 contains elements similar to the previous embodiments and thus the description of these elements will not be repeated. However, in this case, the capping structure 410 is a silicone or epoxy mixture that contains a base of silicone or epoxy 430 and glass particles 432, 434. The glass particles 432, 434 can be formed from small crystallized glass balls 432 and/or irregular glass particles 434. The glass may be powderized and then mixed with the silicone or epoxy 430 prior to being applied to the LED 400, and the mixture then allowed to set. The silicon and/or epoxy base 430 is a transparent non-glass base material into which the glass particles 432, 434 are introduced. This technique enables the use of substantially the same production processes as are used currently while simultaneously reducing the amount of problematic silicone or epoxy and increasing the transparency of the encapsulation material.

Although an LED has been described above in which the light is emitted outward from the top of the structure, other LEDs or light-emitters (e.g., semiconductor lasers) may benefit from a similar arrangement. For example, LEDs in which light emission is from the side of the structure rather than the top can employ the same package. In addition, although not shown, an anti-reflection coating may be disposed on one or more of the surfaces through which light is emitted in the various embodiments above.

It will be understood that the terms and expressions used herein have the ordinary meaning as is accorded to such terms and expressions with respect to their corresponding respective areas of inquiry and study except where specific meanings have otherwise been set forth herein. Further, although the singular term has been used throughout the specification to describe various features, multiples of these features are intended to be encompassed.

Those skilled in the art will recognize that a wide variety of modifications, alterations, and combinations can be made with respect to the above described embodiments without departing from the spirit and scope of the invention defined by the claims, and that such modifications, alterations, and combinations are to be viewed as being within the inventive concept. Thus, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

1. A light emitting diode (LED) comprising:
a semiconductor die that emits light of a first wavelength when activated;
a conductive flange to which the die connected via a thermally conductive adhesive;
a reflector having a cavity in which the die and flange are disposed; and
a glass capping structure attached to the reflector via a capping adhesive such that the glass capping structure seals the cavity.

2. The LED of claim 1, wherein the glass capping structure is a single piece of solid glass.

3. The LED of claim 2, wherein the glass capping structure is a hat.

4. The LED of claim 3, further comprising a layer of phosphor disposed on a surface of the glass capping structure most proximate to the die, the phosphor emitting light of a second wavelength different from the first wavelength when excited by the light from the die.

5. The LED of claim 1, wherein the glass capping structure comprises a plurality of glass layers attached to each other through a transparent adhesive and a layer of phosphor disposed between at least one pair of adjacent glass layers, the phosphor emitting light of a second wavelength different from the first wavelength when excited by the light from the die.

6. The LED of claim 5, wherein the transparent adhesive contains the phosphor.

7. The LED of claim 5, wherein a layer of phosphor is disposed on a surface of the glass capping structure most proximate to the die.

8. The LED of claim 5, wherein the glass layers have uniform dimensions.

9. The LED of claim 5, wherein the glass layers have uniform dimensions.

10. The LED of claim 5, wherein at least some of the glass layers have different dimensions.

11. The LED of claim 10, wherein the glass layers decrease in at least one of length or width with increasing distance from the die.

12. The LED of claim 10, wherein the glass layers decrease in thickness with increasing distance from the die.

13. The LED of claim 1, wherein the cavity is evacuated.

14. The LED of claim 1, wherein the cavity is filled with a transparent material.

15. The LED of claim 1, wherein the glass capping structure comprises a mixture that contains glass particles in a transparent non-glass base material.

16. A method of fabricating a light emitting diode (LED) comprising:
providing a reflector structure containing a semiconductor die, a conductive flange attached to the die via a thermally conductive adhesive, and reflector having a cavity in which the die and attached flange are disposed, the die emitting light of a first wavelength when activated;
sealing the cavity using a glass capping structure attached to the reflector structure, the glass capping structure having a layer of phosphor coated on at least one surface thereof, the phosphor emitting light of a second wavelength different from the first wavelength when excited by the light from the die.

17. The method of claim 16, wherein the glass capping structure is a single piece of solid glass formed as a hat.

18. The method of claim 16, wherein the glass capping structure comprises a plurality of glass layers attached to each other through a transparent adhesive, the phosphor layer disposed between at least one pair of adjacent glass layers.

19. The method of claim 16, wherein the cavity is sealed in a low pressure chamber and then sealing the cavity using the glass capping structure such that the sealed cavity is evacuated.

20. The method of claim 16, further comprising filling the cavity containing the die with a transparent material and then sealing the cavity using the glass capping structure such that the cavity remains filled with the transparent material.
